(19) United States
(12) Patent Application Publication
(10) Pub. No.: US 2026/0060110 A1
(43) Pub. Date: Feb. 26, 2026

(54) CERAMIC SUBSTRATE AND METHOD FOR MANUFACTURING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 19/102,350

(22) PCT Filed: Jul. 19, 2023
(86) PCT No.: PCT/KR2023/010348

§ 371 Date: Feb. 7, 2025

(30) Foreign Application Priority Data
Aug. 8, 2022 (KR) 10-2022-0098294

(51) Int. Cl. H01L 23/498; H01L 21/48; H01L 23/13; H01L 23/15

(52) U.S. Cl. CPC H01L 23/49838; H01L 21/4807; H01L 21/486; H01L 23/13; H01L 23/15

(57) ABSTRACT

The present invention relates to a ceramic substrate and a method for manufacturing the same, the ceramic substrate comprising: a ceramic base material; a first electrode pattern and a second electrode pattern formed on the upper and lower surfaces of the ceramic base material; and a third electrode pattern which is formed on the upper surface of the ceramic base material and is spaced apart from the first electrode pattern, wherein a volume ratio obtained by dividing the total volume of the first electrode pattern by the total volume of the second electrode pattern may be 0.9 to 1.1.

### TECHNICAL FIELD

Embodiments of the present disclosure relate to a ceramic substrate and a method for manufacturing the same, and more particularly, to a ceramic substrate that can be downsized by implementing a driving circuit on a ceramic substrate for power modules and a method for manufacturing the same.

### BACKGROUND ART

Power semiconductor chips are the basic parts of electronic systems as rectifiers and switches, and include diodes, transistors, thyristors, and the like. In addition, IC integrated circuits have been developed with the development of drive IC technology, and such IC integrated circuits can process high-voltage and high-current signals compared to voltages and currents of general digital or analog ICs.

In the case of power modules, implementation of high efficiency, miniaturization, and heat dissipation performance is emerging as competitiveness depending on usage environments from high-voltage and high-current semiconductor chips. In general, since power inverters or motor driving circuit devices for electric vehicles, home appliances, multi-function peripherals, refrigerators, washing machines, and the like are separately used due to the characteristics of different circuits and elements, there is a problem in that it is difficult to implement many performances due to limitations in the volume and size of the module and miniaturization is difficult.

The contents described in the Background Art are to help the understanding of the background of the disclosure, and may include contents that are not a disclosed conventional technology.

### DISCLOSURE

### Technical Problem

An object of the present disclosure is to provide a ceramic substrate that can achieve high efficiency and miniaturization by applying a semiconductor device part and a driving circuit for power modules or a general control drive IC part to one substrate, increase reliability by suppressing a warpage phenomenon caused by a difference in volume between upper and lower electrode patterns, and improve electrical characteristics by preventing oxidation of the electrode patterns, and a method for manufacturing the same.

### Technical Solution

A ceramic substrate according to embodiments of the present disclosure includes: a ceramic base material; a first electrode pattern and a second electrode pattern formed on upper and lower surfaces of the ceramic base material; and a third electrode pattern formed on the upper surface of the ceramic base material while being spaced apart from the first electrode pattern, wherein a volume ratio obtained by dividing a total volume of the first electrode pattern by a total volume of the second electrode pattern may be 0.9 to 1.1.

A silver plating layer may be formed on an outer surface of the first electrode pattern.

A part of the upper surface of the ceramic base material may be formed as a stepped surface in a downwardly recessed shape, and the first electrode pattern may be formed on the stepped surface.

The ceramic base material may include: a plurality of via holes formed to penetrate the upper and lower surfaces; and a metal filler filled in the via hole, wherein the second electrode pattern and the third electrode pattern may be formed to come into contact with exposed upper and lower surfaces of the metal filler.

A depth at which the part of the upper surface of the ceramic base material is recessed downward may be the same as a thickness of the first electrode pattern. A thickness of the first electrode pattern may be larger than a thickness of the third electrode pattern.

The first electrode pattern may be configured such that a power semiconductor chip is mounted, and the third electrode pattern may be configured such that a drive IC chip is mounted.

The second electrode pattern may be formed over an entire lower surface of the ceramic base material to face the first electrode pattern and the third electrode pattern.

The upper surface of the ceramic base material may be divided into a first region and a second region on both sides of the upper surface based on a virtual dividing line, the first region may be formed as the stepped surface and disposed with the first electrode pattern, and the second region may be disposed with the third electrode pattern. The first region may be located lower than the second region, and an area of the first region may be larger than an area of the second region.

A manufacturing method of a ceramic substrate according to embodiments of the present disclosure includes: preparing a ceramic base material; forming a first electrode pattern and a second electrode pattern on upper and lower surfaces of the ceramic base material; and forming a third electrode pattern on the upper surface of the ceramic base material while being spaced apart from the first electrode pattern, wherein in the forming of the first electrode pattern and the second electrode pattern, the first electrode pattern and the second electrode pattern are formed such that a volume ratio obtained by dividing a total volume of the first electrode pattern by a total volume of the second electrode pattern may be 0.9 to 1.1.

The forming of the first electrode pattern and the second electrode pattern may include forming a silver plating layer on an outer surface of the first electrode pattern.

The preparing of the ceramic base material may include forming a stepped surface in which a part of the upper surface of the ceramic base material is recessed downward, wherein the first electrode pattern may be formed on the stepped surface.

The preparing of the ceramic base material may further include: forming a plurality of via holes penetrating the upper and lower surfaces of the ceramic base material; filling the via hole with a metal filler; and sintering the metal filler.

The second electrode pattern and the third electrode pattern may be formed to come into contact with exposed upper and lower surfaces of the metal filler.

In the forming of the stepped surface, a depth at which the part of the upper surface of the ceramic base material is recessed downward may be the same as a thickness of the first electrode pattern.

In the forming of the third electrode pattern, the third electrode pattern may be formed by screen printing a conductive paste. In the forming of the third electrode pattern, the third electrode pattern may be formed by a thin film process.

The forming of the third electrode pattern may further include sintering.

### Advantageous Effects

The present disclosure can achieve high efficiency, miniaturization, and lightness by implementing a semiconductor device part and a driving circuit for power modules or a general control drive IC part to be able to operate on a single substrate.

In addition, the present disclosure can suppress a warpage phenomenon caused by a volume difference by adjusting the volume ratio of a first electrode pattern and a second electrode pattern formed on upper and lower surfaces of the ceramic base material to be in the range of 0.9 to 1.1.

In addition, the present disclosure can prevent a first electrode pattern from being oxidized when a sintering process is performed for strengthening a bonding strength of a third electrode pattern by forming a silver plating layer on an outer surface of the first electrode pattern on which a power semiconductor chip is mounted.

In addition, according to the present disclosure, when voltage, current, and signal connections are required between a second electrode pattern formed on a lower surface of a ceramic base material and a third electrode pattern on which a drive IC chip is mounted, the second electrode pattern and the third electrode pattern are connected with a metal filler filled in a via hole to increase the current movement efficiency and enable miniaturization of the power module.

In addition, according to the present disclosure, since a first electrode pattern is formed on a stepped surface in which a part of an upper surface of a ceramic base material is recessed downward, even though the first electrode pattern is formed thicker than a third electrode pattern, the height difference with the third electrode pattern can be reduced, thereby reducing the position adjustment time of a capillary during wire bonding by about 1/3.

In addition, the present disclosure can be utilized in various fields from electronic components to the energy field because it is a hybrid type dual in line (DIL) structure in which a power module substrate and a drive IC are integrated.

In addition, according to the present disclosure, a third electrode pattern thinner than a first electrode pattern and formed as a fine pattern is formed by screen printing, thereby enabling precise pattern printing while automatically correcting a pattern position during printing.

### DESCRIPTION OF DRAWINGS

FIG. 1 is a perspective view illustrating a ceramic substrate according to an embodiment of the present disclosure.

FIG. 2 is an exploded perspective view illustrating the ceramic substrate an embodiment of the present disclosure.

FIG. 3 is a plan view illustrating the ceramic substrate according to an embodiment of the present disclosure.

FIG. 4 is a cross-sectional view along line a-a′ in FIG. 3.

FIG. 5 is a cross-sectional view illustrating a state in which the ceramic substrate in FIG. 4 is convexly warped upward.

FIG. 6 is a photograph illustrating surfaces before and after sintering of ceramic substrates manufactured according to an embodiment of the present disclosure and comparative examples 1 to 3.

FIG. 7 is an enlarged plan view of a region A in FIG. 3.

FIG. 8 is a side view illustrating a state in which a power semiconductor chip and a drive IC chip are mounted on the ceramic substrate according to an embodiment of the present disclosure and wires are connected.

FIG. 9 is an exploded perspective view illustrating a ceramic substrate according to another embodiment of the present disclosure.

FIG. 10 is a cross-sectional view illustrating the ceramic substrate according to another embodiment of the present disclosure.

FIG. 11 is a partially enlarged view of the ceramic substrate according to another embodiment of the present disclosure.

FIG. 12 is a partially perspective view illustrating a state in which a drive IC chip is mounted on the ceramic substrate according to another embodiment of the present disclosure and wires are connected.

FIG. 13 is a flowchart for describing a method for manufacturing the ceramic substrate according to an embodiment of the present disclosure.

FIG. 14 is a partial cross-sectional view for describing the method for manufacturing the ceramic substrate according to an embodiment of the present disclosure.

FIG. 15 is a partial cross-sectional view for describing a method for manufacturing the ceramic substrate according to another embodiment of the present disclosure.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

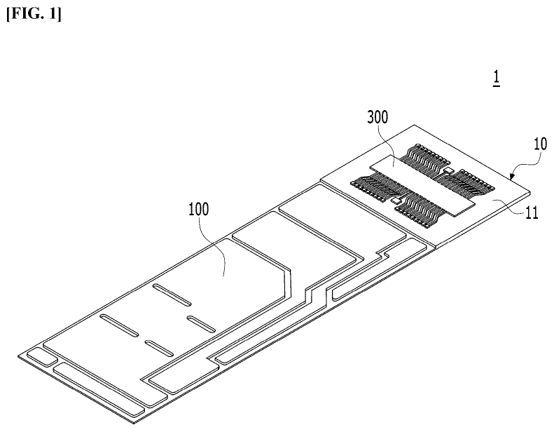

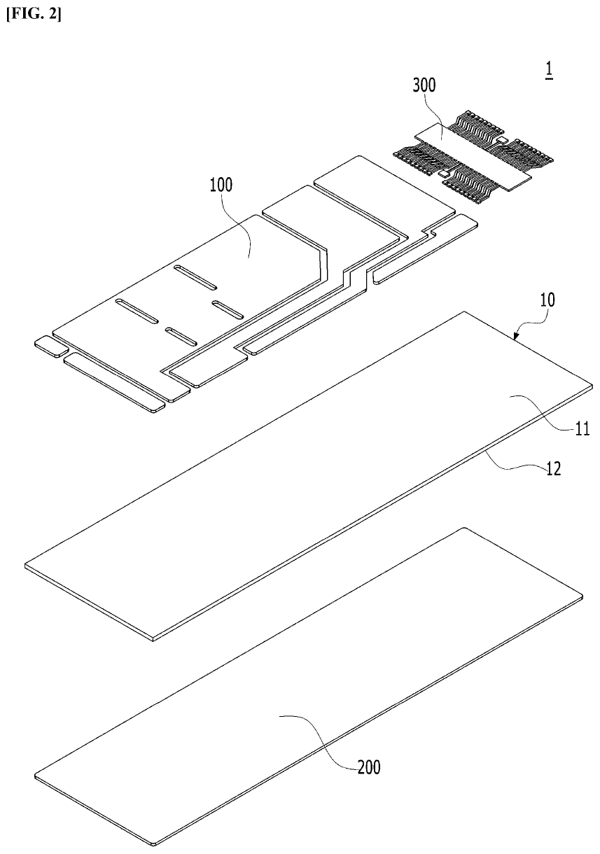

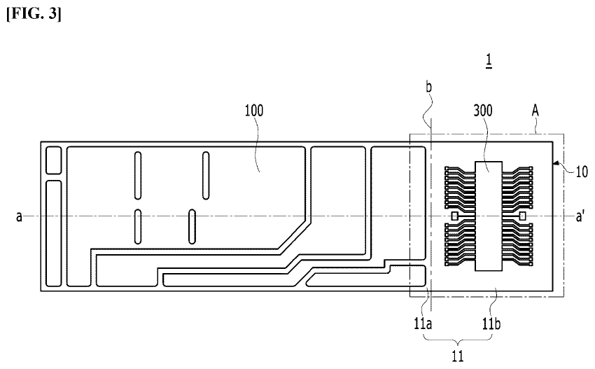

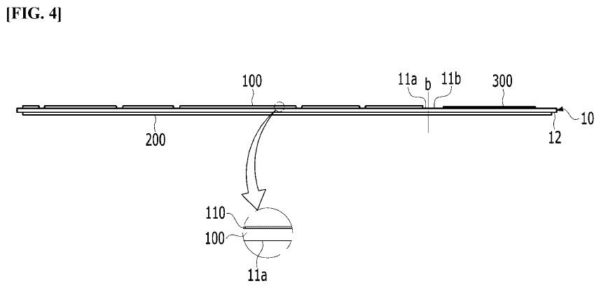

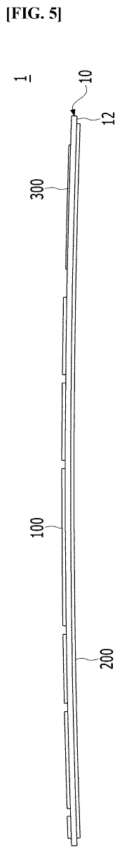

FIG. 1 is a perspective view illustrating a ceramic substrate according to an embodiment of the present disclosure, FIG. 2 is an exploded perspective view illustrating the ceramic substrate an embodiment of the present disclosure, FIG. 3 is a plan view illustrating the ceramic substrate according to an embodiment of the present disclosure, FIG. 4 is a cross-sectional view along line a-a′ in FIG. 3, and FIG. 5 is a cross-sectional view illustrating a state in which the ceramic substrate in FIG. 4 is convexly warped upward.

As illustrated in FIGS. 1 to 3, a ceramic substrate 1 according to an embodiment of the present disclosure may include a ceramic base material 10, a first electrode pattern 100, a second electrode pattern 200, and a third electrode pattern 300.

The ceramic base material 10 may be, for example, any one of alumina (Al₂O₃), AlN, SiN, and Si₃N₄. A thickness of the ceramic base material 10 is 0.3 mm to 0.4 mm. For example, the thickness of the ceramic base material 10 may be prepared to be 0.32 mm or 0.38 mm.

The first electrode pattern 100 and the second electrode pattern 200 may be formed on upper and lower surfaces 11 and 12 of the ceramic base material 10. The third electrode pattern 300 may be formed on the upper surface 11 of the ceramic base material 10 while being spaced apart from the first electrode pattern 100. Specifically, the upper surface 11 of the ceramic base material 10 may be divided into a first region 11a and a second region 11b on both sides of the upper surface 11 based on a virtual dividing line b (see FIGS. 3 and 4). The first region 11a and the second region 11b may form the same plane. In addition, an area of the first region 11a may be formed larger than an area of the second region 11b. The first electrode pattern 100 may be disposed in the first region 11a, and the third electrode pattern 300 may be disposed in the second region 11b.

The first electrode pattern 100 and the second electrode pattern 200 may each be provided as a metal foil, brazed to the upper surface 11 and the lower surface 12 of the ceramic base material 10, and formed into electrode patterns by subsequent etching, machining, etc. The brazing may use a brazing layer made of an alloy material including at least one of Ag, AgCu, and AgCuTi. The heat treatment for brazing may be performed at 780° C. to 900° C. Such a ceramic substrate 1 is referred to as an active metal brazing (AMB) substrate, and such an AMB substrate has excellent durability and heat dissipation performance. The embodiment describes an AMB substrate as an example, but a direct bonding copper (DBC) substrate and a thick printing copper (TPC) substrate may also be applied.

The present embodiment describes an example in which the second electrode pattern 200 is formed in a flat shape to facilitate heat exchange when the second electrode pattern 200 is bonded to a heat sink (not illustrated), etc., but the second electrode pattern 200 may be formed in a circuit pattern shape depending on a semiconductor chip, product specifications, etc. The first electrode pattern 100 and the second electrode pattern 200 may be made of one of Cu, Cu alloy (CuMo, etc.), and Al, for example, and may be preferably made of Cu or Cu alloy. The first electrode pattern 100 and the second electrode pattern 200 may be formed to have a thickness of 0.127 mm to 20 mm.

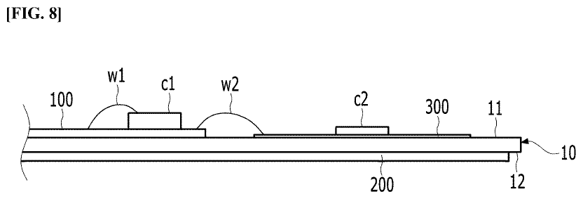

The first electrode pattern 100 may be configured such that a power semiconductor chip c1 (see FIG. 8) is mounted. For example, the first electrode pattern 100 may be mounted with a SiC and GaN-based power semiconductor chip c1 that can respond to use in high voltage, high current, high temperature operation, and high frequency environments and requirements such as high-speed switching, minimization of power loss, and small chip size. In addition to a SiC chip and a GaN chip, the first electrode pattern 100 may be mounted with various elements such as a Si chip, a metal oxide semiconductor field effect transistor (MOSFET), an insulated gate bipolar transistor (IGBT), a junction field effect transistor (JFET), a high electric mobility transistor (HEMT), and a diode. Such a first electrode pattern 100 may have a plurality of electrodes disposed in a predetermined pattern.

The third electrode pattern 300 may be configured such that a drive IC chip c2 is mounted (see FIG. 8). For example, the third electrode pattern 300 may be mounted with a driving, electrical, and electronic control element based on a silicon on insulator (SOI). The third electrode pattern 300 may be made of one of Ag, Au, Pt, Cu, Ag alloy, and carbon black, for example.

Since the first electrode pattern 100 may be configured such that the power semiconductor chip c1 is mounted and is a portion where a large current flows and the third electrode pattern 300 is configured such that the drive IC chip c2 is mounted and is a portion where a small current flows, the first electrode pattern 100 may be formed thicker than the third electrode pattern 300. For example, the thickness of the first electrode pattern 100 may be about 0.3 mm, and the thickness of the third electrode pattern 300 may be about 20 μm; however, the present disclosure is not limited thereto.

A volume ratio obtained by dividing a total volume of the first electrode pattern 100 by a total volume of the second electrode pattern 200 may be 0.9 to 1.1. That is, the volume ratio obtained by dividing the total volume of the first electrode pattern 100 disposed on the upper surface of the ceramic substrate 1 by the volume of the second electrode pattern 200 disposed on the lower surface of the ceramic substrate 1 may be designed to be within 0.9 to 1.1.

Since the first electrode pattern 100 is formed as an electrode pattern on which a power semiconductor chip is mounted, a volume difference occurs with respect to the second electrode pattern 200 formed as a flat plate, and when the volume difference is large, a phenomenon in which the ceramic substrate 1 is warped in a high-temperature environment occurs as illustrated in FIG. 5. Since the thickness of the third electrode pattern 300 is about 20 μm, it is very thin compared to the first electrode pattern 100 and the second electrode pattern 200, and thus does not have a significant influence on a warpage. In addition, since the coefficient of thermal expansion of the ceramic base material 10 is about 2 ppm/K to 6 ppm/K, it does not have a significant influence on a warpage even though the shape of the ceramic base material 10 is changed.

On the other hand, the first electrode pattern 100 and the second electrode pattern 200 each have a thickness of about 0.3 mm or more and are each made of materials such as Cu and Al with excellent thermal conductivity. Since these materials have a coefficient of thermal expansion of 17.8 ppm/K or more, there is a problem in that a warpage occurs significantly depending on the temperature.

Since the first electrode pattern 100 has a pattern shape configured such that a power semiconductor chip is mounted, it is often difficult to change a design shape such as thickness and length. Accordingly, the ceramic substrate 1 according to an embodiment of the present disclosure can calculate the total volume of the first electrode pattern 100 formed on the upper surface 11 of the ceramic base material 10, and control the thickness of the second electrode pattern 200 to have a predetermined volume in correspondence with the calculated volume, thereby suppressing a warpage phenomenon occurring at a high temperature.

The volume ratio obtained by dividing the total volume of the first electrode pattern 100 by the total volume of the second electrode pattern 200 is preferably designed to be within the range of 0.9 to 1.1, and the volume ratio is more preferably designed to be close to 1.0 in order to minimize a warpage. The total volume may be calculated as the product of a total area and a thickness.

For example, in a case where the total volume is 305.94081 mm³ when the thickness of the first electrode pattern 100 is 0.3 mm and the area of the first electrode pattern 100 is 1019.8027 mm² and the total volume is 449.208 mm³ when the thickness of the second electrode pattern 200 is 0.3 mm and the area of the second electrode pattern 200 is 1497.3600 mm², the volume ratio of the first electrode pattern 100/the second electrode pattern 200 is about 0.68. In this way, when the total volume of the second electrode pattern 200 is larger than the total volume of the first electrode pattern 100, a negative warpage phenomenon in which the ceramic substrate 1 is convexly warped upward occurs as illustrated in FIG. 5.

On the other hand, when the area of the second electrode pattern 200 is the same as 1497.3600 mm² but the thickness thereof is changed from 0.3 mm to 0.2 mm, since the total volume of the second electrode pattern 200 is 299.472 mm³, the total volume of the second electrode pattern 200 is almost the same as the total volume 305.94081 mm³ of the first electrode pattern 100 and the volume ratio of the first electrode pattern 100/second electrode pattern 200 is about 1.0.

That is, by simply adjusting the thickness of the second electrode pattern 200, the volume ratio of the first electrode pattern 100/second electrode pattern 200 can be adjusted to be within the range of 0.9 to 1.1, thereby suppressing a warpage caused by the volume difference. In this way, the present disclosure can calculate a volume by using the total area and thickness of the first electrode pattern 100 and adjust the thickness of the second electrode pattern 200 in correspondence with the volume of the first electrode pattern 100, thereby controlling the volume ratio of the first electrode pattern 100/second electrode pattern 200 to be within a specific range and thus actively and stably controlling a warpage of the ceramic substrate according to the temperature.

The third electrode pattern 300 may be formed by screen printing a conductive paste. Since the third electrode pattern 300 is formed as a fine pattern having a line and space shape of 100 μm to 150 μm, it may be precisely formed when a method of screen printing a conductive paste is applied. Since the standard of the line and space is a thickness, the line and space shape of the third electrode pattern 300 formed thinner than the first electrode pattern 100 is finer than that of the first electrode pattern 100. The screen printing method may precisely implement such a fine pattern. The screen printing is suitable for forming a fine pattern because it has a high curing speed and excellent adhesiveness and flexibility. In addition, when a table on which a product is seated is disposed under a screen mask and a screen process is performed, since a program automatically corrects the position of the table through a reference index hole on the side while performing printing, pattern printing is precisely possible at a correct position.

The third electrode pattern 300 may also be formed by a thin film process. The thin film process may form a metal thin film by a method such as deposition, coating, or application and then form a desired pattern by using a pattern mask. The thin film process may be applied when a fine pattern having a line and space shape of 15 μm to 30 μm is formed to have a maximum thickness of 2 μm.

In this way, the third electrode pattern 300 formed on the upper surface 11 of the ceramic base material 10 by the screen printing or the thin film process may be subjected to a sintering process in which heat of 350° C. to 600° C. is applied to strengthen the bonding strength. The sintering process may be performed in an oxidizing atmosphere, and the oxidizing atmosphere may mean an air atmosphere containing some oxygen or an atmosphere in which oxygen is mixed with an inert gas such as nitrogen or argon.

When the sintering process is performed on the third electrode pattern 300 at a temperature of 200° C. or higher in an oxidizing atmosphere, the first electrode pattern 100 made of Cu material is easily oxidized and turns black, and becomes an insulator. Since the first electrode pattern 100 is a portion where the power semiconductor chip c1 is mounted, when oxidation occurs, the electrical characteristics deteriorate and reliability decreases. When heat treatment is additionally performed under a reducing atmosphere containing hydrogen in order to remove oxidation, metal oxide is reduced to metal as oxygen is separated, but the process steps are complicated and the properties may be changed. Accordingly, in the ceramic substrate 1 according to an embodiment of the present disclosure, a silver plating layer 110 may be formed on an outer surface of the first electrode pattern 100 in order to prevent oxidation of the first electrode pattern 100. The silver plating layer 110 may be made of Ag or an Ag alloy, and may effectively prevent oxidation of the first electrode pattern 100 due to the high oxidation resistance of Ag. The silver plating layer 110 may be formed before the third electrode pattern 300 is formed by the screen printing or the thin film process. Such a silver plating layer 110 may be formed to cover exposed outer surfaces of the first electrode pattern 100 formed in the first region 11a, that is, the upper surface and the outer side surfaces thereof. The silver plating layer 110 may be formed by electroless plating, which is simple in process and inexpensive in cost, but is not limited thereto.

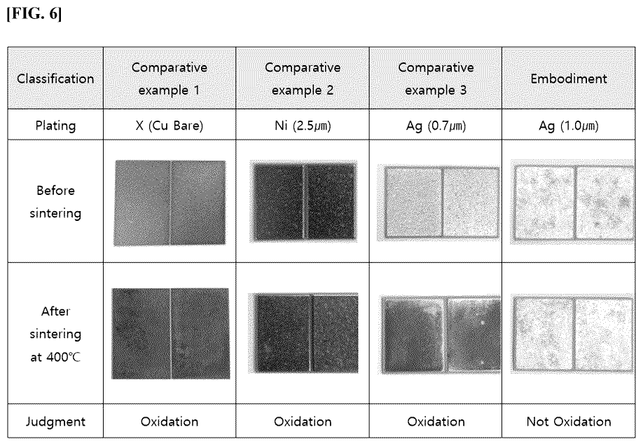

FIG. 6 is a photograph illustrating surfaces before and after sintering of ceramic substrates manufactured according to an embodiment of the present disclosure and comparative examples 1 to 3.

The silver plating layer 110 is preferably formed to have a thickness of 1 μm or more. Referring to FIG. 6, in the case of comparative example 1 using a Cu metal pattern on which no plating layer is formed, it can be confirmed that the metal pattern is oxidized and turns black when a sintering process is performed at 400° C. in an oxidizing atmosphere. Even in the case of comparative example 2 where a Ni plating layer is formed with a thickness of 2.5 μm on a Cu metal pattern, it can be confirmed that the metal pattern is oxidized and turns black after a sintering process is performed at 400° C. Referring to comparative example 3 and the embodiment, it can be confirmed that in the comparative example 3 where an Ag plating layer is formed with a thickness of 0.7 μm on a Cu metal pattern, oxidation occurs when a sintering process is performed at 400° C. in an oxidizing atmosphere, but in the embodiment where an Ag plating layer is formed with a thickness of 1 μm on a Cu metal pattern, no oxidation occurs. In this way, it can be confirmed that when the silver plating layer 110 is formed to have a thickness of 1 μm or more on the outer surface of the Cu metal pattern, the Cu metal pattern can be prevented from being oxidized.

The silver plating layer 110 may effectively prevent oxidation of the first electrode pattern 100 on which the power semiconductor chip c1 is mounted, without affecting the quality required for the ceramic substrate such as solderability or wire bondability. The solderability is a measure of the wettability of soldering, and in the case of a ceramic substrate having a silver plating layer of 1 μm or more formed on a Cu electrode pattern, the ceramic substrate has been confirmed to have good solderability by showing an average measurement value of 95% or more. The wire bondability is a measure of the adhesive strength between a bonding wire and a bonding portion, and is good when the shear force is 700 g or more. In the case of a ceramic substrate having a silver plating layer of 1 μm or more formed on a Cu electrode pattern, the ceramic substrate has been confirmed to have good bondability by showing an average measurement value of 1272 g or more.

The second electrode pattern 200 may be formed with a wide area over the entire lower surface 12 of the ceramic base material 10 in order to facilitate heat transfer. The second electrode pattern 200 may have one area facing the first electrode pattern 100 and the other area facing the third electrode pattern 300.

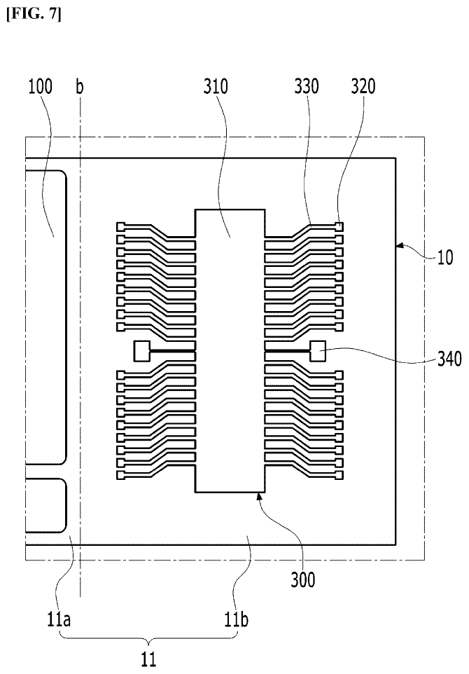

FIG. 7 is an enlarged plan view of a region A in FIG. 3.

As illustrated in FIG. 7, the third electrode pattern 300 may include a first pattern region 310 configured such that the drive IC chip c2 is mounted, a second pattern region 320 to which one end of a second wire w2 is bonded, a third pattern region 330 connecting the first pattern region 310 and the second pattern region 320, and a fourth pattern region 340 extending from the center to both sides of the first pattern region 310. The second pattern region 320 may be disposed in plural on both sides of the first pattern region 310, and the third pattern region 330 may extend to both sides of the first pattern region 310 by a certain length in order to connect the first pattern region 310 and the second pattern region 320.

FIG. 8 is a side view illustrating a state in which a power semiconductor chip and a drive IC chip are mounted on the ceramic substrate according to an embodiment of the present disclosure and wires are connected.

As illustrated in FIG. 8, the power semiconductor chip c1 may be bonded to the first electrode pattern 100 and connected to the first electrode pattern 100 by a first wire w1. The first wire w1 may be an Al wire, but is not limited thereto. The drive IC chip c2 may be bonded to the first pattern region 310 of the third electrode pattern 300, and the second pattern region 320 of the third electrode pattern 300 may be connected to the first electrode pattern 100 by a second wire w2. The second wire w2 may be made of Au, but is not limited thereto.

In this way, the ceramic substrate 1 according to an embodiment of the present disclosure is a ceramic substrate 1 having a dual electrode structure in which two functional chips, that is, the power semiconductor chip c1 and the drive IC chip c2 are mounted on the upper surface 11 of the ceramic base material 10. The ceramic substrate 1 having such a dual electrode structure has the advantages of being able to reduce the size, reduce the weight, increase the heat dissipation efficiency, and be applied to home appliances, electric vehicle modules, etc., in various ways, compared to when the drive IC module and the power module are separately provided.

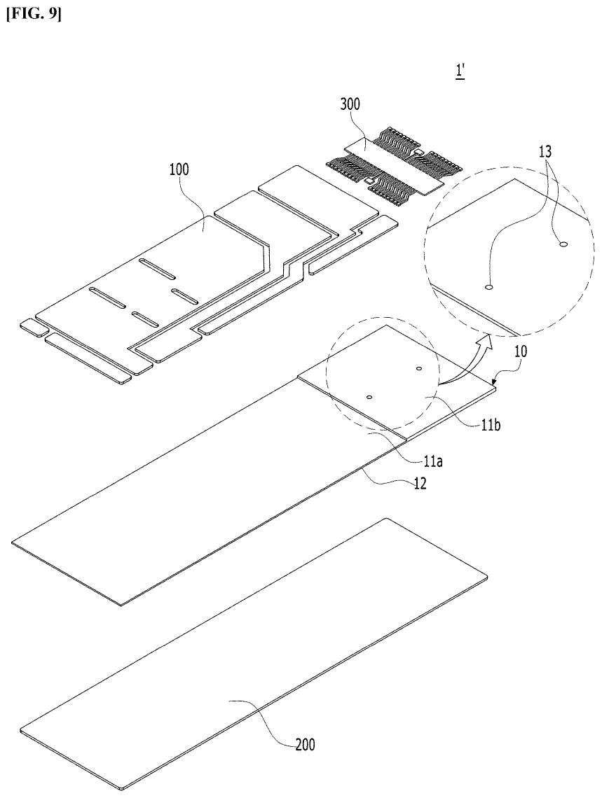

The structure of a ceramic substrate according to another embodiment of the present disclosure is described below with reference to FIGS. 9 to 12. For the convenience of explanation, the same components as those of the embodiment illustrated in FIGS. 1 to 8 are not described, and differences are mainly described below.

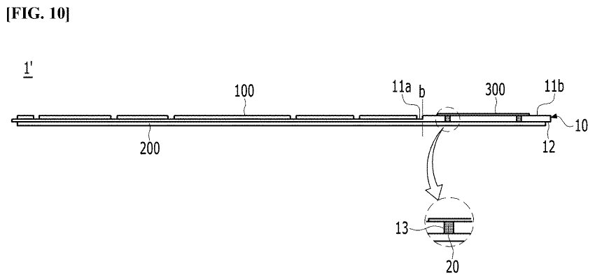

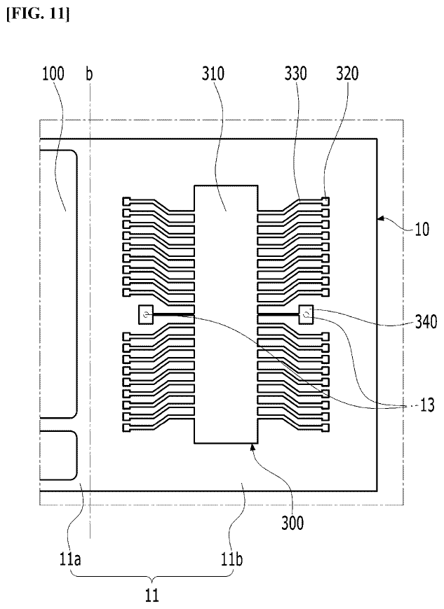

FIG. 9 is an exploded perspective view illustrating a ceramic substrate according to another embodiment of the present disclosure, FIG. 10 is a cross-sectional view illustrating the ceramic substrate according to another embodiment of the present disclosure, and FIG. 11 is a partially enlarged view of the ceramic substrate according to another embodiment of the present disclosure.

Referring to FIGS. 9 and 10, a ceramic substrate 1′according to another embodiment of the present disclosure may include a plurality of via holes 13 provided in a ceramic base material 10. The plurality of via holes 13 may be formed to penetrate upper and lower surfaces 11 and 12 of the ceramic base material 10, and a metal filler 20 may be filled in the via holes 13. The metal filler 20 may be any one of Ag, W, Mo, and an Ag alloy, but is not limited thereto. The metal filler 20 filled in the via hole 13 may be fixed to the via hole 13 through a sintering process, and may conduct electricity between the second electrode pattern 200 and the third electrode pattern 300 facing each other while interposing the via hole 13 therebetween.

The via hole 13 is formed in a region where the second electrode pattern 200 and the third electrode pattern 300 face each other. Accordingly, the second electrode pattern 200 and the third electrode pattern 300 may come into contact with exposed upper and lower surfaces of the metal filler 20 filled in the via hole 13. Since the ceramic base material 10 is made of an insulating material, an electrical connection between the electrode patterns formed on the upper surface 11 and the lower surface 12 is not possible. Accordingly, when voltage, current, and signal connections are required between the second electrode pattern 200 formed on the lower surface 12 of the ceramic base material 10 and the third electrode pattern 300 on which the drive IC chip c2 is mounted, the second electrode pattern 200 and the third electrode pattern 300 may be connected with the metal filler 20 filled in the via hole 13 to increase the current movement efficiency and enable miniaturization of the power module.

Referring to FIG. 11, the fourth pattern region 340 of the third electrode pattern 300 may be formed at a position corresponding to the via hole 13. In the present embodiment, the total number of via holes 13 is 2, but is not limited thereto. The via hole 13 is preferably formed to have a diameter of 0.1 mm or more and 0.3 mm or less. When the via hole 13 is formed to have a diameter of 0.1 mm or more and 0.3 mm or less, the metal filler 20 may be filled in the via hole 13 without voids. The diameter of the via hole 13 may be formed corresponding to the thickness of the ceramic base material 10. For example, when the thickness of the ceramic base material 10 is 0.38 mm, the diameter of the via hole 13 is preferably formed to be 0.1 mm or more and 0.2 mm or less in correspondence with the thickness of the ceramic base material, and when the diameter of the via hole 13 exceeds 0.2 mm, the filling efficiency may decrease and the metal filler 20 may fall out of the via hole 13 after sintering.

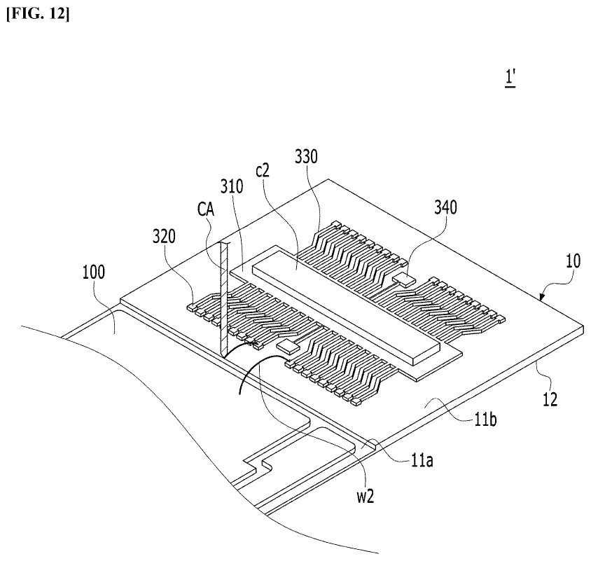

FIG. 12 is a partially perspective view illustrating a state in which a drive IC chip is mounted on the ceramic substrate according to another embodiment of the present disclosure and wires are connected.

Referring to FIG. 12, in a state in which the drive IC chip c2 is mounted on the first pattern region 310 of the third electrode pattern 300, the second pattern region 320 of the third electrode pattern 300 and the first electrode pattern 100 may be connected with the second wire w2 by using a capillary CA.

The capillary CA for performing the wire bonding process may form a first bonding portion on the upper side of the second pattern region 320 of the third electrode pattern 300, then move upward in the vertical direction, and then move to the first electrode pattern 100 to form a second bonding portion. In such a case, since the thickness of the third electrode pattern 300 is about 20 μm and the thickness of the first electrode pattern 100 is about 0.3 mm, there is a height difference of about 280 μm. Accordingly, since time is required to adjust the upper and lower positions of the capillary CA, which are adjusted to the thickness of the third electrode pattern 300, to match the thickness of the first electrode pattern 100, the manufacturing time may increase accordingly.

In order to solve such a problem, the ceramic substrate 1′according to another embodiment of the present disclosure can reduce a height difference between the first electrode pattern 100 and the third electrode pattern 300 by forming a part of the upper surface 11 of the ceramic base material 10 in a stepped manner.

Specifically, the upper surface 11 of the ceramic base material 10 may be divided into a first region 11a and a second region 11b on both sides of the upper surface 11 based on a virtual dividing line b (see FIGS. 9 and 10), wherein the first region 11a may be formed as a stepped surface in a downwardly recessed shape, located lower than the second region 11b, and formed to have a larger area than the second region 11b. The first electrode pattern 100 may be formed on the first region 11a being a stepped surface in a downwardly recessed shape. Accordingly, even though the first electrode pattern 100 is formed thicker than the third electrode pattern 300, the height difference with the third electrode pattern 300 formed in the second region 11b that is not recessed can be reduced. In such a case, the depth at which a part of the upper surface 11 of the ceramic base material 10 is recessed downward may be the same as the thickness of the first electrode pattern 100. In this way, by reducing the height difference between the first electrode pattern 100 and the third electrode pattern 300, the position adjustment time of the capillary can be reduced by about 1/3.

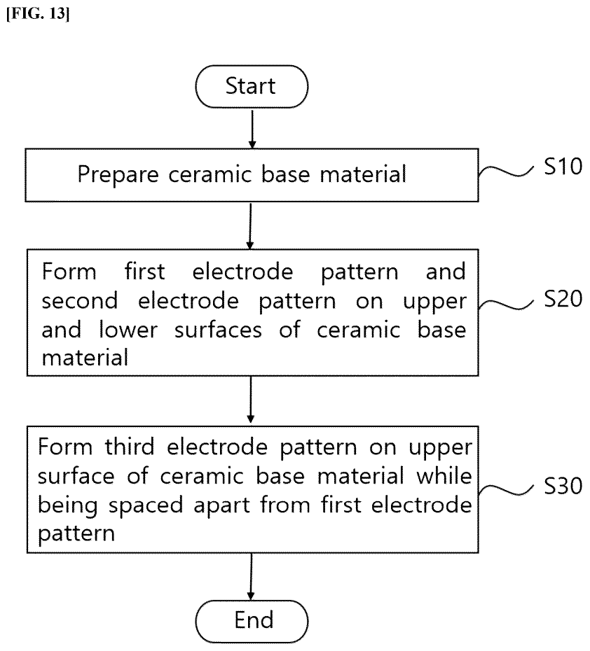

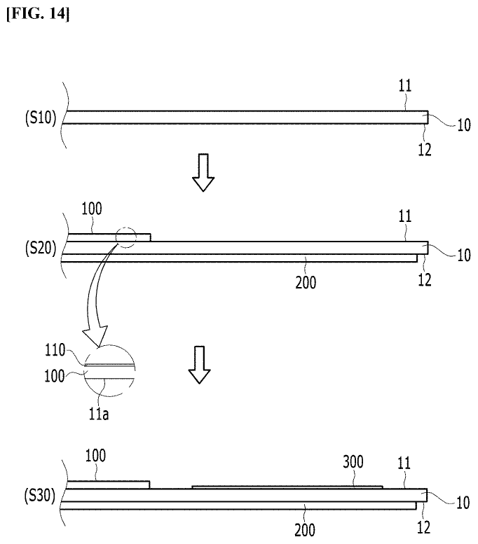

FIG. 13 is a flowchart for describing a method for manufacturing the ceramic substrate according to an embodiment of the present disclosure, and FIG. 14 is a view for describing the method for manufacturing the ceramic substrate according to an embodiment of the present disclosure.

As illustrated in FIGS. 13 and 14, the method for manufacturing the ceramic substrate according to an embodiment of the present disclosure may include step S10 of preparing the ceramic base material 10, step S20 of forming the first electrode pattern 100 and the second electrode pattern 200 on the upper and lower surfaces 11 and 12 of the ceramic base material 10, and step S30 of forming the third electrode pattern 300 on the upper surface 11 of the ceramic base material 10 while being spaced apart from the first electrode pattern 100.

In step S10 of preparing the ceramic base material 10, the ceramic base material 10 is prepared using any one of materials such as alumina (Al₂O₃), AlN, SiN, Si₃N₄, and zirconia toughed alumina (ZTA). The thickness of the ceramic base material 10 is 0.3 mm to 0.4 mm. For example, the thickness of the ceramic base material 10 prepared may be 0.32 mm or 0.38 mm.

In step S20 of forming the first electrode pattern 100 and the second electrode pattern 200 on the upper and lower surfaces 11 and 12 of the ceramic base material 10, the first electrode pattern 100 may be formed on the first region 11a of the upper surface 11 of the ceramic base material 10 and the second electrode pattern 200 may be formed on the lower surface 12 of the ceramic base material 10.

In step S20 of forming the first electrode pattern 100 and the second electrode pattern 200, the first electrode pattern 100 and the second electrode pattern 200 may each be provided as a metal foil, brazed to the upper surface 11 and the lower surface 12 of the ceramic base material 10, and formed into electrode patterns by subsequent etching, machining, etc. The brazing may use a brazing layer made of an alloy material including at least one of Ag, AgCu, and AgCuTi. The heat treatment for brazing may be performed at 780° C. to 900° C. The first electrode pattern 100 and the second electrode pattern 200 may be made of one of Cu, Cu alloy (CuMo, etc.), and Al, for example.

In step S20 of forming the first electrode pattern 100 and the second electrode pattern 200, the volume ratio obtained by dividing the total volume of the first electrode pattern 100 by the total volume of the second electrode pattern 200 may be 0.9 to 1.1. Since the first electrode pattern 100 has a pattern shape configured such that a power semiconductor chip is mounted, it is often difficult to change a design shape such as thickness and length. Accordingly, the method for manufacturing the ceramic substrate according to an embodiment of the present disclosure can calculate the total volume of the first electrode pattern 100 formed on the upper surface 11 of the ceramic base material 10, and adjust the thickness of the second electrode pattern 200 to have a predetermined volume in correspondence with the calculated volume, thereby suppressing a warpage phenomenon occurring at a high temperature. That is, by simply adjusting the thickness of the second electrode pattern 200, the volume ratio of the first electrode pattern 100/second electrode pattern 200 may be adjusted to be within the range of 0.9 to 1.1, it is possible to suppress a warpage caused by the volume difference. In this way, the present disclosure can calculate a volume by using the total area and thickness of the first electrode pattern 100 and adjust the thickness of the second electrode pattern 200 in correspondence with the volume of the first electrode pattern 100, thereby controlling the volume ratio of the first electrode pattern 100/second electrode pattern 200 to be within a specific range and thus actively and stably controlling a warpage of the ceramic substrate according to the temperature.

In step S30 of forming the third electrode pattern 300 on the upper surface 11 of the ceramic base material 10 while being spaced apart from the first electrode pattern 100, the third electrode pattern 300 may be formed by screen printing a conductive paste. Since the third electrode pattern 300 is formed as a fine pattern having a line and space shape of 100 μm to 150 μm, the third electrode pattern 300 is preferably formed by screen printing a conductive paste. Since the standard of the line and space is a thickness, the line and space shape of the third electrode pattern 300 formed thinner than the first electrode pattern 100 is finer than that of the first electrode pattern 100. In order to precisely implement such a fine pattern, screen printing is preferable. The screen printing is suitable for forming a fine pattern because it has a high curing speed and excellent adhesiveness and flexibility. In addition, when a table on which a product is seated is disposed under a screen mask and a screen process is performed, since a program automatically corrects the position of the table through a reference index hole on the side while performing printing, pattern printing is precisely possible at a correct position.

In step S30 of forming the third electrode pattern 300 on the upper surface 11 of the ceramic base material 10 while being spaced apart from the first electrode pattern 100, the third electrode pattern 300 may also be formed by a thin film process. The thin film process may form a metal thin film by a method such as deposition, coating, or application and then form a desired pattern by using a pattern mask. The thin film process may be applied when a fine pattern having a line and space shape of 15 μm to 30 μm is formed to have a maximum thickness of 2 μm.

Step S30 of forming the third electrode pattern 300 may further include step of sintering. In the step of sintering, a sintering process may be performed at 350° C. to 600° C. to strengthen the bonding strength of the third electrode pattern 300 formed on the upper surface 11 of the ceramic base material 10 by the screen printing or the thin film process. In such a case, the sintering process may be performed in an oxidizing atmosphere, and the oxidizing atmosphere may mean an air atmosphere containing some oxygen or an atmosphere in which oxygen is mixed with an inert gas such as nitrogen or argon.

When the sintering process is performed on the third electrode pattern 300 at a temperature of 200° C. or higher in an oxidizing atmosphere, the first electrode pattern 100 made of Cu material is easily oxidized and turns black, and becomes an insulator. Since the first electrode pattern 100 is a part where the power semiconductor chip c1 is mounted, when oxidation occurs, the electrical characteristics deteriorate and reliability decreases. When heat treatment is additionally performed under a reducing atmosphere containing hydrogen in order to remove oxidation, metal oxide is reduced to metal as oxygen is separated, but the process steps are complicated and the properties may be changed.

Accordingly, the method for manufacturing the ceramic substrate according to an embodiment of the present disclosure may include a step of forming the silver plating layer 110 on the outer surface of the first electrode pattern 100 before step S30 of forming the third electrode pattern 300. That is, step S20 of forming the first electrode pattern 100 and the second electrode pattern 200 may include a step of forming the silver plating layer 110 on the outer surface of the first electrode pattern 100. The silver plating layer 110 may be formed by electroless plating, which is simple in process and inexpensive in cost, and may be formed to cover the exposed outer surfaces of the first electrode pattern 100, that is, the upper surface and the outer side surfaces thereof. The silver plating layer 110 may be made of Ag or an Ag alloy, and may effectively prevent oxidation of the first electrode pattern 100 due to the high oxidation resistance of Ag. The silver plating layer 110 is preferably formed to have a thickness of 1 μm or more. The silver plating layer 110 formed to have a thickness of 1 μm or more can effectively prevent oxidation of the first electrode pattern 100, on which the power semiconductor chip c1 is mounted, without affecting the quality required for the ceramic substrate such as solderability or wire bondability.

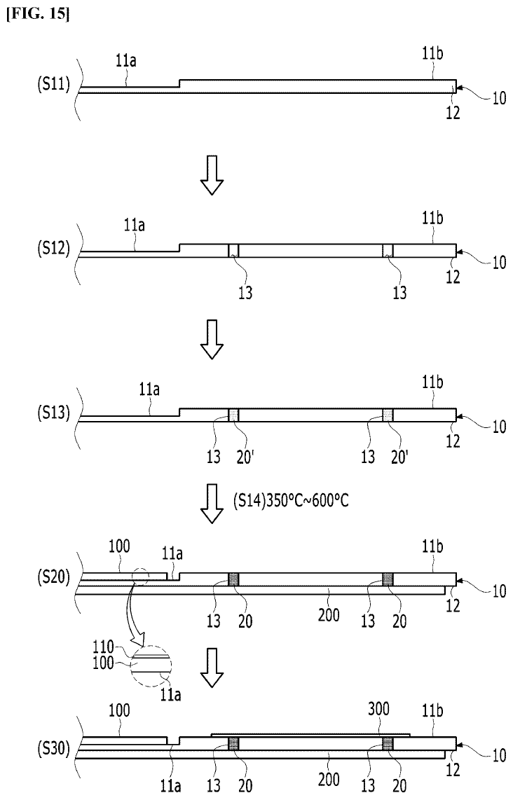

FIG. 15 is a partial cross-sectional view for describing a method for manufacturing the ceramic substrate according to another embodiment of the present disclosure.

Referring to FIG. 15, step S10 of preparing the ceramic base material 10 may include step S11 of forming a stepped surface in which a part of the upper surface 11 of the ceramic base material 10 is recessed downward, step S12 of forming the plurality of via holes 13 penetrating the upper and lower surfaces 11 and 12 of the ceramic base material 10, step S13 of filling the via holes 13 with a metal filler 20′, and step S14 of sintering the metal filler 20′. In step S11 of forming the stepped surface, the depth at which a part of the upper surface 11 of the ceramic base material 10 is recessed downward may be the same as the thickness of the first electrode pattern 100.

Step S12 of forming the plurality of via holes 13 penetrating the upper and lower surfaces 11 and 12 of the ceramic base material 10 may form the plurality of via holes 13 penetrating the upper and lower surfaces 11 and 12 of the ceramic base material 10 by using a laser drilling method or a photo via method. The via holes 13 may be formed in a region where the second electrode pattern 200 and the third electrode pattern 300 face each other so as to connect the second electrode pattern 200 and the third electrode pattern 300. In the present embodiment, the total number of via holes 13 is 2, but is not limited thereto.

The via hole 13 is preferably formed to have a diameter of 0.1 mm or more and 0.3 mm or less. When the via hole 13 is formed to have a diameter of 0.1 mm or more and 0.3 mm or less, the metal filler 20 may be filled in the via hole 13 without voids. The diameter of the via hole 13 may be formed corresponding to the thickness of the ceramic base material 10. For example, when the thickness of the ceramic base material 10 is 0.38 mm, the diameter of the via hole 13 is preferably formed to be 0.1 mm or more and 0.2 mm or less in correspondence with the thickness of the ceramic base material 10, and when the diameter of the via hole 13 exceeds 0.2 mm, the filling efficiency may decrease and the metal filler 20 may fall out of the via hole 13 after sintering.

In step S13 of filling the via hole 13 with the metal filler 20′, the metal filler 20′in the form of metal ink (paste) may be filled in the via hole 13. The metal filler 20′may be any one of Ag, W, Mo, and Ag alloy, but is not limited thereto.

In step S14 of sintering, the metal filler 20′filled in the via hole 13 may be changed into a solidified metal filler 20 through a drying and sintering process and may be fixed to the via hole 13. Step S14 of sintering may be performed in a temperature range of 350° C. to 600° C., but may be performed at various temperatures depending on the metal filler.

After the metal filler 20′is filled in the via hole 13 of the ceramic base material 10 and is dried, a metal layer provided as a metal foil may be brazed to the upper surface 11 and the lower surface 12 of the ceramic base material 10. The drying process may temporarily fix the state in which the metal filler 20′is filled in the via hole 13, and in the brazing process performed in step S20 of forming the first electrode pattern 100 and the second electrode pattern 200, the metal filler 20′may be sintered and become the solidified metal filler 20.

In the method for manufacturing the ceramic substrate according to another embodiment of the present disclosure, step S20 of forming the first electrode pattern 100 and the second electrode pattern 200 and step S30 of forming the third electrode pattern 300 may be performed in the same manner as the method for manufacturing the ceramic substrate according to an embodiment.

In step S20 of forming the first electrode pattern 100 and the second electrode pattern 200, the first electrode pattern 100 may be formed on the first region 11a that is a stepped surface in a downwardly recessed shape. Accordingly, even though the first electrode pattern 100 is formed thicker than the third electrode pattern 300, the height difference with the third electrode pattern 300 formed in the second region 11b that is not recessed can be reduced. In such a case, the depth at which a part of the upper surface 11 of the ceramic base material 10 is recessed downward may be the same as the thickness of the first electrode pattern 100. In this way, by reducing the height difference between the first electrode pattern 100 and the third electrode pattern 300, the position adjustment time of the capillary for performing the wire bonding process can be reduced by about 1/3.

In addition, step S20 of forming the first electrode pattern 100 and the second electrode pattern 200 may form the first and second electrode patterns 100 and 200 so that the volume ratio obtained by dividing the total volume of the first electrode pattern 100 by the total volume of the second electrode pattern 200 is within the range of 0.9 to 1.1. That is, by calculating the total volume of the first electrode pattern 100 formed in the first region 11a of the upper surface 11 of the ceramic base material 10 and adjusting the thickness of the second electrode pattern 200 to have a predetermined volume corresponding to the calculated volume, it is possible to suppress a warpage phenomenon occurring at a high temperature.

The above description is merely intended to illustratively describe the technical spirit of the present disclosure, and various changes and modifications can be made by those skilled in the art to which the present disclosure pertains without departing from the essential features of the present disclosure. Therefore, the embodiments disclosed in the present disclosure are not intended to limit the technical spirit of the present disclosure, but are intended to describe the present disclosure. The scope of the technical spirit of the present disclosure is not limited by these embodiments. The scope of the present disclosure should be interpreted by the accompanying claims and all technical spirits falling within the equivalent scope thereto should be interpreted as being included in the scope of the present disclosure.

1. A ceramic substrate comprising:
a ceramic base material;
a first electrode pattern and a second electrode pattern formed on upper and lower surfaces of the ceramic base material; and
a third electrode pattern formed on the upper surface of the ceramic base material while being spaced apart from the first electrode pattern,
wherein a volume ratio obtained by dividing a total volume of the first electrode pattern by a total volume of the second electrode pattern is 0.9 to 1.1.

2. The ceramic substrate of claim 1, wherein a silver plating layer is formed on an outer surface of the first electrode pattern.

3. The ceramic substrate of claim 1, wherein a part of the upper surface of the ceramic base material is formed as a stepped surface in a downwardly recessed shape, and
the first electrode pattern is formed on the stepped surface.

4. The ceramic substrate of claim 1, wherein the ceramic base material comprises:
a plurality of via holes formed to penetrate the upper and lower surfaces; and
a metal filler filled in the via hole,
wherein the second electrode pattern and the third electrode pattern are formed to come into contact with exposed upper and lower surfaces of the metal filler.

5. The ceramic substrate of claim 3, wherein a depth at which the part of the upper surface of the ceramic base material is recessed downward is the same as a thickness of the first electrode pattern.

6. The ceramic substrate of claim 1, wherein a thickness of the first electrode pattern is larger than a thickness of the third electrode pattern.

7. The ceramic substrate of claim 1, wherein the first electrode pattern is configured such that a power semiconductor chip is mounted, and
the third electrode pattern is configured such that a drive IC chip is mounted.

8. The ceramic substrate of claim 1, wherein the second electrode pattern is formed over an entire lower surface of the ceramic base material to face the first electrode pattern and the third electrode pattern.

9. The ceramic substrate of claim 3, wherein the upper surface of the ceramic base material is divided into a first region and a second region on both sides of the upper surface based on a virtual dividing line,
the first region is formed as the stepped surface and disposed with the first electrode pattern, and the second region is disposed with the third electrode pattern.

10. The ceramic substrate of claim 9, wherein the first region is located lower than the second region.

11. The ceramic substrate of claim 9, wherein an area of the first region is larger than an area of the second region.

12. A method for manufacturing a ceramic substrate, the method comprising:
preparing a ceramic base material;
forming a first electrode pattern and a second electrode pattern on upper and lower surfaces of the ceramic base material; and
forming a third electrode pattern on the upper surface of the ceramic base material while being spaced apart from the first electrode pattern,
wherein in the forming of the first electrode pattern and the second electrode pattern, the first electrode pattern and the second electrode pattern are formed such that a volume ratio obtained by dividing a total volume of the first electrode pattern by a total volume of the second electrode pattern is 0.9 to 1.1.

13. The method of claim 12, wherein the forming of the first electrode pattern and the second electrode pattern comprises:
forming a silver plating layer on an outer surface of the first electrode pattern.

14. The method of claim 12, wherein the preparing of the ceramic base material comprises:
forming a stepped surface in which a part of the upper surface of the ceramic base material is recessed downward,
wherein the first electrode pattern is formed on the stepped surface.

15. The method of claim 12, wherein the preparing of the ceramic base material further comprises:
forming a plurality of via holes penetrating the upper and lower surfaces of the ceramic base material;
filling the via hole with a metal filler; and
sintering the metal filler.

16. The method of claim 15, wherein the second electrode pattern and the third electrode pattern are formed to come into contact with exposed upper and lower surfaces of the metal filler.

17. The method of claim 14, wherein, in the forming of the stepped surface, a depth at which the part of the upper surface of the ceramic base material is recessed downward is the same as a thickness of the first electrode pattern.

18. The method of claim 12, wherein, in the forming of the third electrode pattern, the third electrode pattern is formed by screen printing a conductive paste.

19. The method of claim 12, wherein, in the forming of the third electrode pattern, the third electrode pattern is formed by a thin film process.

20. The method of claim 12, wherein the forming of the third electrode pattern further comprises sintering.
